(19) United States
(12) Patent Application Publication
(10) Pub. No.: US 2025/0334610 A1
(43) Pub. Date: Oct. 30, 2025

(54) PROBE CARD FOR A TESTING APPARATUS OF ELECTRONIC DEVICES AND CORRESPONDING SPACE TRANSFORMER

(71) Applicant: TECHNOPROBE S.P.A., Cernusco Lombardone (LC) (IT)

(72) Inventor: Stefano FELICI, Cernusco Lombardone (LC) (IT)

(73) Assignee: TECHNOPROBE S.P.A., Cernusco Lombardone (LC) (IT)

(21) Appl. No.: 18/867,147

(22) PCT Filed: May 23, 2023
(86) PCT No.: PCT/EP2023/063736

§ 371 Date: Nov. 19, 2024

(30) Foreign Application Priority Data
May 25, 2022 (IT) 102022000010940

(51) Int. Cl. G01R 1/073; G01R 31/28

(52) U.S. Cl. CPC G01R 1/07378; G01R 1/07314; G01R 31/2889

(57) ABSTRACT

A probe card mounted in an of electronic device testing apparatus is described, having a probe head housing a plurality of contact probes, each having a first end portion which abuts onto contact pads of a device under test, a main board and a connected intermediate board which provides a distance spatial transformation between contact pads made on opposite faces thereof. The intermediate board is a space transformer which includes a plurality of modules that are plate-shaped and coplanar, and structurally and functionally independent from each other. Each module has a first face facing towards the probe head and a first plurality of contact pads whereonto respective second end portions of the contact probes abut and an opposite second face facing towards the main board. The second face has a second plurality of contact pads connected to the first plurality of contact pads.

### TECHNICAL FIELD

The present invention relates to a probe card for a testing apparatus of electronic devices.

The invention relates particularly, but not exclusively, to a probe card comprising an intermediate board being a space transformer interposed between a plurality of contact probes and a board for connection to a testing apparatus and the following description is made with reference to this field of application with the only purpose of simplifying the exposition thereof.

### BACKGROUND ART

As it is well known, a probe card is essentially a device adapted to electrically connect a plurality of contact pads of a microstructure, in particular an electronic device integrated on a wafer, with corresponding channels of a testing apparatus that performs the test thereof.

The test performed on integrated devices is used in particular to detect and isolate defective devices as early as in the production phase. Normally, the probe cards are thus used for the electrical test of the devices integrated on wafers or chips before cutting or singulating and assembling them inside a containment package.

A probe card comprises a probe head essentially including in turn a plurality of movable contact elements or contact probes provided with at least one end portion or contact tip adapted to abut onto a corresponding plurality of contact pads of the device under test. The term end or tip indicates here and below an end portion, being not necessarily pointed.

It is well known that the efficacy and reliability of a measuring test just depends, among other factors, on creating a good electrical connection between the device under test and the testing apparatus, and thus, on establishing an optimum probe/pad electrical contact.

Among the types of probe heads used in the here-considered technical field for the test of the devices integrated on wafers, the so-called vertical probe heads are widespread, in which the contact probes are arranged substantially perpendicular to the device under test.

In particular, a vertical probe head comprises a plurality of contact probes usually retained by a pair of plates or guides, that are plate-shaped and parallel to each other. These guides are located at a certain distance from each other so as to leave a free space or air gap for the movement and possible deformation of the contact probes and they are provided with appropriate guide holes adapted to slidingly house said contact probes. More particularly, the pair of guides comprises an upper guide (upper die) and a lower guide (lower die), both equipped with guide holes through which the contact probes axially slide, usually made of wires of special alloys with good electrical and mechanical properties, the term lower conventionally indicating the guide that is closer to the device under test.

The good connection between the contact probes of the probe head and the contact pads of the device under test is ensured by pressing the probe head on the device itself, the contact probes, which are movable inside the guide holes made in the upper and lower guides, undergoing, during said pressing contact, a bending, inside the air gap between the two guides, and a sliding inside the guide holes housing them.

Furthermore, the bending of the contact probes in the air gap can be helped and guided through a suitable configuration of the probes themselves or of the guides, using in particular pre-deformed contact probes or suitably transversely shifting the guides comprising them.

In general, probe heads with probes that are not fixedly fastened, but kept interfaced to an appropriate main plate or main board, connected in turn to the testing apparatus are used: they are referred to as unblocked probe heads. Said main board is also indicated as main board or main PCB, since it is usually made using the techniques of printed circuits or PCBs (from the English: “Printed Circuit Board”), a technology that allows boards with active areas having even a large size to be formed, although with major limitations with respect to a minimum reachable value for the distance (pitch) between the contact pads and thus usually reserved just to the main board, that has less stringent distance constraints than the device under test due to the use of an intermediate board or space transformer that has contact pads made on opposite faces thereof at a different distance, suitably connected to each other by means of connections made inside the space transformer itself.

In this case, the contact probes have a further end portion or contact head adapted to abut onto a plurality of contact pads of the space transformer. The good electrical contact between contact probes and space transformer is ensured similarly to the contact with the device under test by pressing the probes onto the contact pads made on the space transformer.

Furthermore, the main board is generally kept in place by means of a stiffener. The assembly of the probe head, main board, intermediate board or space transformer and stiffener forms a probe card, globally and schematically indicated with 10 in FIG. 1.

In particular, the probe card 10 comprises a probe head 1, in the example of the Figure comprising a plurality of vertical probes 2, adapted to abut onto contact pads 3A of a device under test 3 integrated on a semiconductor wafer 3′. In this case, the probe head 1 comprises in turn at least one upper guide 4 and a lower guide 5, having respective upper guide holes 4A and lower guide holes 5A through which the contact probes 2 slide.

Each contact probe 2 has at least one first end portion or contact tip 2A that abuts onto a contact pad 3A of the device under test 3, performing the mechanical and electrical contact between the device under test and a testing apparatus (not represented) which said probe head 1 forms an end element of.

Moreover, each contact probe 2 has a second end portion, usually indicated as contact head 2B, between the contact tip 2A and the contact head 2B extending the probe body 2C along a longitudinal development axis of the contact probe 2.

The contact head 2B is adapted in turn to perform the contact with a plurality of contact pads 6A made on an intermediate board 6, that in particular is a space transformer, and is connected to a main board 7, connected in turn to the actual testing apparatus.

The spatial transformation performed by the intermediate board 6 relates in particular the distances between the centres of the contact pads made on opposite faces thereof; in particular, said intermediate board 6 comprises a first plurality of contact pads 6A made on a first face FA thereof facing towards the probe head 1 in correspondence of the contact heads 2B of the contact probes 2 and connected by means of suitable metallizations 6C to a second plurality of contact pads 6B made on a second opposite face FB thereof facing towards the main board 7, said second plurality of contact pads 6B having a different spatial distribution, in particular with the centres of the pads at a greater distance, that is having greater pitches than the pitch of the first plurality of contact pads 6A, that are instead distributed in a manner substantially corresponding to the contact pads 3A of the device under test 3. The intermediate board 6 thereby performs the spatial transformation, in particular with a distancing of the contact pads 6B made on the second face FB thereof with respect to the contact pads 6A made on the first face FA thereof. The contact pads 6A of the first plurality and the contact pads 6B of the second plurality are commonly indicated as probe side or fine pitch pads and PCB side or large pitch pads, respectively.

The good electrical contact between contact probes 2 and intermediate board 6 is ensured similarly to the contact with the device under test 3 by pressing the probes onto the contact pads 6A made on the first face FA of the intermediate board 6.

As already indicated, the main board 7 is also kept in place by means of a stiffener 8.

In the embodiment illustrated in FIG. 1, the probe head 1 comprises a further intermediate guide 5′ (medium guide), that is plate-shaped and parallel to the upper guide 4 and to the lower guide 5 and arranged therebetween, preferably close to the lower guide 5, the intermediate guide 5′ being in turn provided with a plurality of intermediate guide holes 5′A in which the contact probes 2 are slidingly housed.

Suitably, the upper guide 4, the lower guide 5 and the intermediate guide 5′ are shifted from each other so as to ensure a preferred bending direction to the contact probes 2, besides a correct retention thereof inside the probe head 1, completed by a housing 9 that integrally connects the guides to each other.

In the vertical probe technology, it is thus important to ensure the good connection of the contact probes to the device under test, in particular in correspondence of the contact tips thereof, and to the testing apparatus, in particular in correspondence of the contact heads thereof and thus at the space transformer, that plays a very important role especially when testing integrated circuits made according to the latest integration technologies that entail contact pads on the devices under test being extremely close and very small in size, such constrains badly reconciling with the PCB technology through which the main board is made.

Different technologies are known for making the space transformer that generally has very small thicknesses, in the range of 0.5-3 mm and has in particular planarity problems.

More particularly, a first known solution is the ceramic-based technology or MLC (acronym for “MultiLayer Ceramic”), that allows a plurality of layers of rigid ceramic material with a high planarity level to be formed, interspersed with conductive layers that connect contact pads made on the opposite faces of the space transformer.

In a space transformer of the MLC type, the conductive paths 6C are made in particular by means of a suitable configuration of the conductive layers and non-conductive layers, for example ceramic ones, overlapped and interspersed with each other.

Alternatively, in place of a ceramic multilayer MLC, it is also known to make a space transformer by means of an organic multilayer (MLO, acronym for “MultiLayer Organic”) associated with a rigid support, for example glued thereto, said MLO including a plurality of layers of organic material that form a plurality of non-conductive layers, one or more conductive layers being arranged on said non-conductive layers in a suitable configuration, adapted to make the conductive paths 6C. The rigid support is preferably a ceramic support.

The mutual positioning of the elements that make up the probe card is an extremely important parameter for a correct operation of the card itself and the several technologies used to make said elements bring planarity problems that complicate the configuration of the card as a whole and especially with respect to the mutual positioning of the intermediate board or space transformer and the main board. Even the presence of the stiffener, that makes the whole assembly more rigid and strong, does not generally allow the planarity defects of the space transformer to be sufficiently eliminated and the correct and full contact thereof with the main board to be ensured.

This is further complicated by the operating temperature of the card itself, in particular in case of testing at extreme temperatures. In fact, in this case, the thermal expansions of the elements that make up the probe card can affect the correct behaviour thereof, due to the different coefficients of thermal expansion of the different materials that form said elements. In fact it is common to fasten the elements that make up a probe card to each other by means of screws, which, in particular during a test in temperature, apply to the different boards a constraint that tends to cause a buckling thereof, with subsequent malfunctioning of the probe card as a whole, to the limit even with the lack of contact thereof with the contact pads of the device under test.

This problem is particularly felt in the case of large-sized probe cards, such as for example the probe cards for testing memory devices like DRAMs. For this type of probe cards, the lack of control of the thermal expansion of the components actually involves considerable problems in the testing phase.

The technical problem underlying the present invention is to provide a probe card, having such structural and functional features as to allow the limitations and drawbacks still affecting the probe cards made with known technologies to be overcome, allowing in particular to ensure a correct planarity of all the different card components even in case of large-sized cards and tests at high temperatures, while having a simple and easy-to-assemble structure.

### DISCLOSURE OF INVENTION

The solution idea underlying the present invention is to provide a probe card having an intermediate board or space transformer structured in a plurality of independent modules, that can be tested and possibly discarded in case of malfunctioning before assembling them in the space transformer, said modules being provided with suitable means for connection to the main board or to an additional support structure.

Based on this solution idea, the technical problem is solved by a probe card adapted to be mounted in a testing apparatus of electronic devices, said probe card comprising at least one probe head that houses a plurality of contact probes, each contact probe having at least one first end portion adapted to abut onto contact pads of a device under test, as well as a main board and an intermediate board, connected to the main board and adapted to provide a distance spatial transformation between contact pads made on opposite faces thereof, said intermediate board being a space transformer, characterized in that said space transformer comprises a plurality of modules that are plate-shaped and coplanar, structurally and functionally independent from each other, each module having a first face facing towards the probe head and provided with a first plurality of contact pads whereonto respective second end portions of the contact probes abut and a second face, opposite the first face and facing towards the main board, said second face being provided in turn with a second plurality of contact pads connected to the first plurality of contact pads by means of electrical connections made inside the module and in that the space transformer comprises a connecting structure made at the second faces of the modules, the modules having a same thickness.

More particularly, the invention comprises the following additional and optional features, taken individually or, if necessary, in combination.

According to an aspect of the invention, the connecting structure of the space transformer can comprise a plurality of connecting areas, each of said connecting areas being made in correspondence of a second face of one of the modules.

Furthermore, each connecting area can have a thickness along a z axis that is orthogonal to the main board of less than 10%, preferably less than 1% of the thickness of each of the modules along said z axis.

According to another aspect of the invention, each connecting area can comprise a welding.

Furthermore, each connecting area can comprise an adhesive film or glue, that is preferably conductive.

According to still another aspect of the invention, the connecting structure can integrally connect the modules of the space transformer to the main board in correspondence of a face thereof facing towards the probe head.

In particular, the face of the main board which the modules are integrally connected to can have a surface roughness of less than 5 microns.

According to another aspect of the invention, the space transformer can further comprise a support and the connecting structure can integrally connect the modules of the space transformer to the support in correspondence of a face thereof facing towards the probe head, said support being in turn integrally connected to the main board.

In particular, the face of the support, which the modules are integrally connected to, can have a surface roughness of less than 5 microns, preferably less than 1 micron.

According to another aspect of the invention, the space transformer can further comprise a plurality of separator elements, that are coplanar to the modules, the separator elements being interposed and interspersed with said modules in a checkerboard configuration, each of the separator elements separating a pair of modules.

In particular, each of the separator elements can comprise a connecting area made in correspondence of a face thereof facing towards the main board, the connecting areas of the separator elements being comprised in the connecting structure of the space transformer.

According to another aspect of the invention, at least one of the separator elements can comprise active and/or passive components, preferably capacitors.

Furthermore, according to another aspect of the invention, each connecting area can be made by means of a single area or comprise a plurality of connecting areas that are distinct from each other and arranged on the second face of the modules.

According to a further aspect of the invention, each of the modules has a plate-like shape, in particular a prismatic shape with a rectangular or hexagonal base.

Finally, according to another aspect of the invention, each of the modules can comprise at least one multilayer, preferably an organic multilayer MLO.

Furthermore, the technical problem is solved by a space transformer adapted to be inserted into a probe card for a testing apparatus of electronic devices, characterized in that it comprises a plurality of modules that are plate-shaped and coplanar, structurally and functionally independent from each other, each module having a first face provided with a first plurality of contact pads and a second face, opposite the first face, said second face being provided in turn with a second plurality of contact pads connected to the first plurality of contact pads by means of electrical connections made inside the module and in that it comprises a connecting structure made in correspondence of the second faces of the modules, the modules having a same thickness.

According to another aspect of the invention, the connecting structure can comprise a plurality of connecting areas, each of said connecting areas being made in correspondence of a second face of one of the modules.

According to still another aspect of the invention, each connecting area can have a thickness of less than 10%, preferably less than 1% of the thickness of each of the modules along a same z axis.

Furthermore, according to another aspect of the invention, each connecting area can comprise a welding or an adhesive film or glue, that is preferably conductive.

The space transformer can further comprise a support, the connecting structure integrally connecting the modules to said support in correspondence of a face thereof.

In particular, the face of the support which the modules are integrally connected to has a surface roughness of less than 5 microns, preferably less than 1 micron.

According to another aspect of the invention, the space transformer can further comprise a plurality of separator elements that are coplanar to the modules, the separator elements being interposed and interspersed with said modules in a checkerboard configuration, each of said separator elements separating a pair of modules.

According to another aspect of the invention, each of said separator elements can comprise a connecting area made in correspondence of a face thereof aligned and corresponding to the second face of the modules, the connecting areas of the separator elements being comprised in the connecting structure of the space transformer.

According to still another aspect of the invention, at least one of said separator elements can comprise active and/or passive components, preferably capacitors.

Furthermore, according to another aspect of the invention, each connecting area can be made by means of a single area or comprise a plurality of connecting areas that are distinct from each other and arranged on the second face of the modules.

According to another aspect of the invention, each of the modules can have a plate-like shape, in particular a prismatic shape with a rectangular or hexagonal base.

Finally, according to another aspect of the invention, each of the modules can comprise at least one multilayer, preferably an organic multilayer MLO.

The features and advantages of the probe card and space transformer according to the invention will be apparent from the following description of exemplary embodiments thereof given by way of non-limiting examples with reference to the attached drawings.

### BRIEF DESCRIPTION OF DRAWINGS

In the drawings:

FIG. 1 shows a schematic sectional view of a probe card comprising a vertical probe head made according to the prior art;

FIG. 2A shows a schematic sectional view of a probe card according to an embodiment of the invention;

FIG. 2B shows a schematic sectional view of a probe card according to an alternative embodiment of the invention;

FIG. 3A shows a top see-through view of an intermediate board being a space transformer contained in the probe card of FIGS. 2A or 2B;

FIG. 3B shows a top see-through view of an alternative embodiment of the intermediate board being a space transformer contained in the probe card of FIGS. 2A or 2B;

FIGS. 4A-4B and 5A-5B show respective sectional views of alternative embodiments of the intermediate board being a space transformer contained in the probe card of FIGS. 2A and 2B, respectively; and

FIGS. 6A and 6B show respective top axonometric views of alternative embodiments of a module contained in the intermediate board being a space transformer of the probe card of FIGS. 2A or 2B.

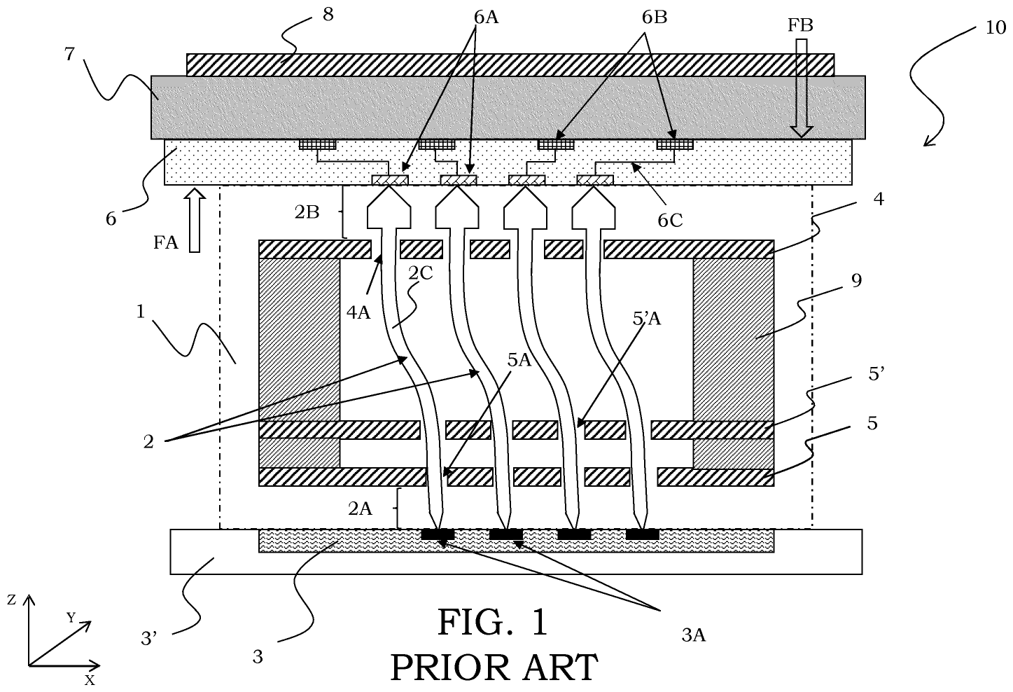

### MODES FOR CARRYING OUT THE INVENTION

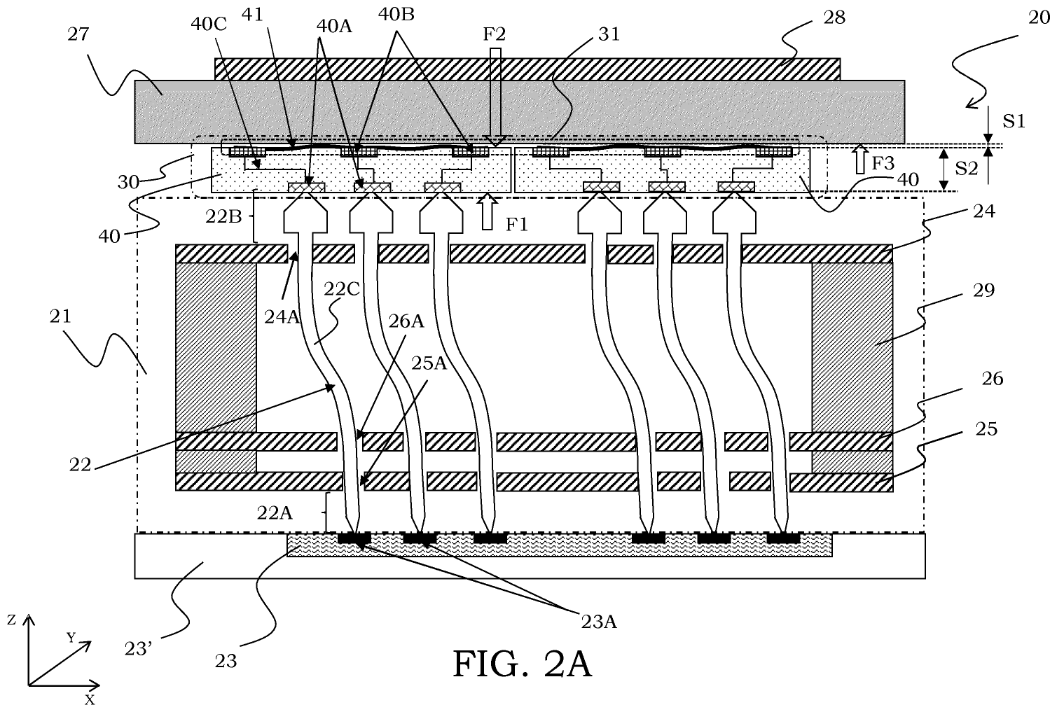

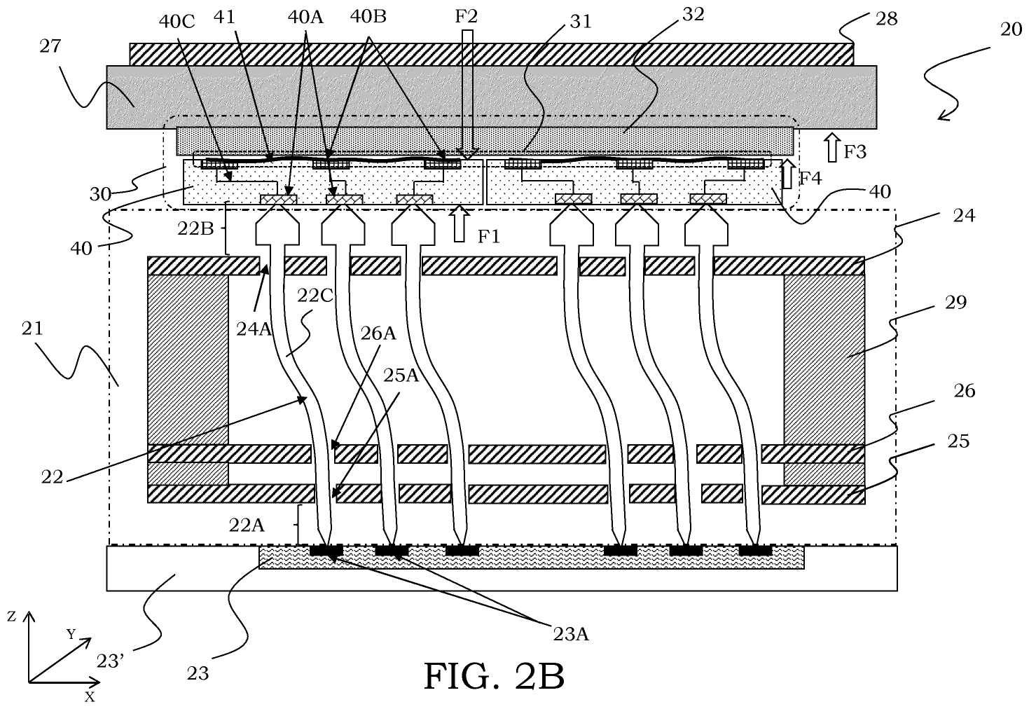

With reference to the Figures, and particularly to FIG. 2A, a probe card comprising at least one probe head provided with a plurality of contact probes for testing electronic devices, particularly integrated on wafers, made according to the present invention, is globally indicated with 20.

It should be noted that the Figures represent schematic views of the card according to the invention and are not drawn to scale, but instead they are drawn so as to emphasize the important features of the invention.

Moreover, the different aspects of the invention represented by way of examples in the Figures can be obviously combined with each other and interchanged from one embodiment to another one.

In particular, as illustrated in FIG. 2A, the probe card 20 comprises a probe head 21 that houses a plurality of contact probes 22. In the example illustrated in the Figure, the probe head 21 is of the vertical type and it comprises at least one upper plate or guide 24 and one lower plate or guide 25, having respective upper guide holes 24A and lower guide holes 25A through which the contact probes 22 slide.

As it is conventional in the technical field of the present invention, the term “lower guide” indicates the guide arranged closer to a device under test and the term “upper guide” indicates the guide arranged closer to a testing apparatus connected to the probe card that includes the probe head.

The probe head 21 also comprises a containment element or housing 29, adapted to encompass the contact probes 22 and to integrally connect the upper guide 24 and the lower guide 25.

In the example illustrated in FIG. 2A, the probe head 21 also comprises an intermediate plate or guide 26, arranged parallel between the upper guide 24 and the lower guide 25, in particular closer to the latter, the intermediate guide 26 being similarly provided with intermediate guide holes 26A through which the contact probes 22 slide. Said three-guide embodiment is merely given by way of example, the probe head 21 being able to comprise any number of guides that is higher or equal to 1.

Each of the contact probes 22 comprises in particular at least one first end portion or contact tip 22A adapted to abut onto a corresponding contact pad 23A of a device under test 23, in particular integrated on a semiconductor wafer 23′, so as to establish the desired contact, in particular an electrical contact, between the contact probes 22 of the probe head 21 and the contact pads 23A of the device under test 23.

Each contact probe 22 further comprises a second end portion or contact head 22B adapted to establish the contact with a main board 27 or main PCB for connection with a testing apparatus (not illustrated). A rod-shaped probe body 22C is arranged between the contact head 22B and the contact tip 22A, substantially along a longitudinal development direction of the contact probe 22, that is in particular orthogonal to a plane whereon the device under test 23 is arranged.

The probe card 20 comprises an intermediate board arranged between the probe head 21 and the main board 27 and adapted to perform a spatial transformation, in particular with respect to the distribution of the contact pads on the opposed faces thereof and therefore indicated with space transformer 30. Suitably according to the present invention, said space transformer 30 is split into a plurality of modules 40, that are coplanar, structurally and functionally independent from each other, each of said modules 40 being plate-shaped (referring to a physical product and not an abstract geometric entity and thus always taking into account process tolerances) and arranged between the probe head 21 and the main board 27, the modules 40 having a same thickness S2, i.e. a same dimension along the z axis that is orthogonal to the development plane of the device under test 23, except for the dimensional tolerances linked to the processes for making said modules 40, still referring to a physical product.

The probe card 20 further comprises a stiffener 28 associated with the main board 27 to improve the planarity thereof, being particularly useful in case of testing in temperature.

Suitably, each module 40 has a first face F1 facing towards the probe head 21 (in operating conditions, i.e. when the space transformer 30 that comprises the modules 40 is inserted into a probe card 20 that is assembled as an end element of a testing apparatus) and comprising a first plurality of contact pads, also indicated as probe side pads 40A, whereonto the contact heads 22B of the contact probes 22 abut. Furthermore, each module 40 has a second face F2, opposite the first face F1 and thus facing (in operating conditions) towards the main board 27 for connection with the testing apparatus, said second face F2 comprising in turn a second plurality of contact pads, also indicated as tester side pads 40B, connected to the plurality of probe side pads 40A by means of respective electrical connections 40C made inside the module 40. The first face F1 and the second face F2 of each module 40 have a greater surface extension, preferably much greater, with respect to the other side faces of said module 40, that is substantially tile-shaped, the modules 40 being arranged so as to cover a desired area of the space transformer 30, corresponding to an area of the semiconductor wafer 23′ comprising the devices under test 23 by means of the probe card 20 that includes said space transformer 30. All the modules 40 make a space transformer 30 in the form of a board, that is similar in size, in particular in thickness, to the one-piece space transformers made according to the prior art, but with an overall greater surface extension, particularly adapted to test memory devices like DRAMs.

Advantageously according to the present invention, each module 40 also comprises at least one connecting area 41, arranged on the second face F2 thereof and adapted to integrally connect it to the main board 27. All the connecting areas 41 of the plurality of modules 40 form a connecting structure 31 of the space transformer 30, adapted to integrally connect it to the main board 27.

In a preferred embodiment, the connecting area 41 is a welding. Alternatively, it is possible to make the connecting area 41 by means of an adhesive film or glue, that is preferably conductive.

Suitably, the connecting area 41 is arranged in particular on the second face F2 of the modules 40 in a substantially planar manner, so as to ensure a correct positioning of the modules 40 with respect to a z axis, that is orthogonal to the main board 27 and in particular to a face F3 thereof facing towards the probe head 21. Moreover, the connecting area 41 has a thickness S1 along the z axis that is negligible with respect to the thickness S2 of each module 40 according to the same axis, so as to reduce the overall dimensions of the connecting structure 31 that comprises the connecting areas 41 of all the modules 40 comprised in the space transformer 30, besides keeping the planarity thereof with respect to the main board 27. In particular, the thickness S1 of the connecting area 41 is less than 10%, preferably less than 1% of the thickness S2 of the module 40, thickness meaning a dimension along the z axis of the connecting area 41 and of the module 40 respectively. In this case too, the proportion between the thicknesses is to be understood net of process tolerances, to be always taken into account when talking about a physical product and not an abstract geometric entity.

According to an embodiment, the face F3 of the main board 27 is suitably made so as to have a planarity which can ensure a correct alignment in z of the modules 40, in particular having a surface roughness Ra of less than 5 microns. It can also be provided that the face F3 of the main board 27 undergoes a planarization process adapted to reduce the surface roughness thereof to the above-indicated desired values.

It should be emphasized that the use of a connecting area 41 made on the second face F2 of the modules 40 allows said modules 40 to be easily positioned on the face F3 of the main board 27, for example by means of a spatial positioning method, in particular an optical alignment one, which can accurately determine the position of said modules 40 on the face F3 of the main board 27. Suitably, the modules 40 are configured to be side by side so as not to leave gaps or empty areas in the space transformer 30, always net of any process tolerance.

In a preferred alternative embodiment of the present invention, schematically illustrated in FIG. 2B, the space transformer 30 also comprises a support 32 which the modules 40 are integrally connected to, by means of respective connecting areas 41, in particular in correspondence of a face F4 of the support 32 facing (in operating conditions) towards the probe head 21.

Suitably, it is possible to make said support 32 using techniques and materials which can ensure a proper planarity to the face F4 thereof whereon the modules 40 are assembled, in particular a surface roughness Ra being less than 5 microns. It should be emphasized that said support 32 cannot be made according to the PCB technology and can thus include materials that are adapted to reach more easily the desired roughness value, and also a surface roughness Ra value being less than 1 micron, no further planarization processes being needed.

The support 32 is thus connected to the main board 27 according to any technique known in the field, such as welding, use of adhesive films or glues, which are in particular conductive, or even by means of a mechanical screw system, the correct positioning of the modules 40 being already ensured by the integral connection thereof to the support 32 itself by means of the connecting structure 31.

It should be emphasized that, advantageously according to the present invention, the space transformer 30 is made by means of a plurality of modules 40 that are structurally and functionally independent from each other, correctly positioned in space xyz by means of the connecting structure 31 that integrally connects them to the main board 27 or to the support 32. The production of the single modules, that can be manufactured and also tested before the assembly in the space transformer 30, is thereby simplified, reducing the final manufacturing costs of said space transformer 30. Moreover it is possible to make said space transformer 30 even with a considerable size, such as for testing memory devices like DRAMs, while keeping the thickness of said space transformer 30 reduced, in particular substantially equal to the thickness S2 of each module 40, without incurring the planarity problems of the one-piece space transformers made according to the prior art.

Advantageously, each module 40 can be made by one of the techniques used in the field for making space transformers. Preferably, each module 40 is made by means of a multilayer, preferably an organic multilayer MLO.

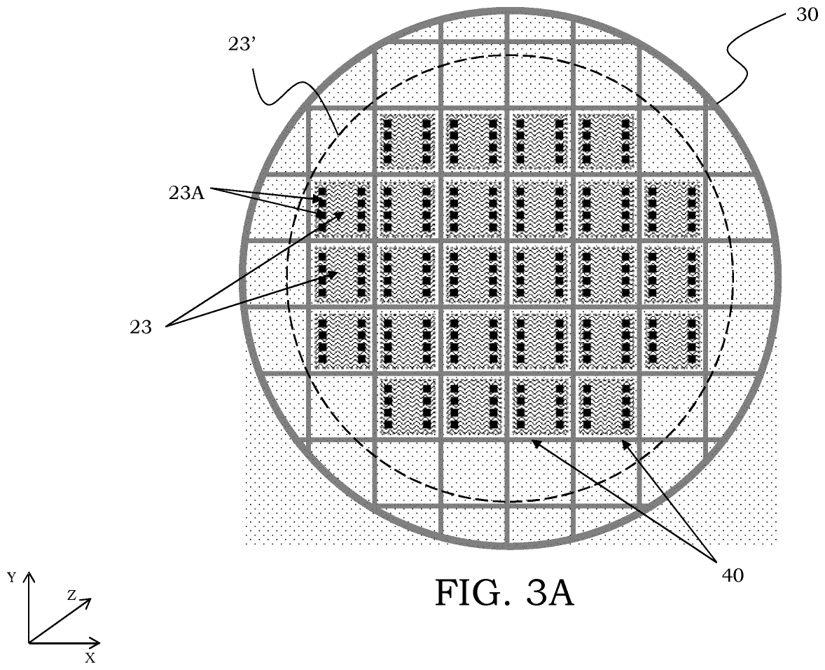

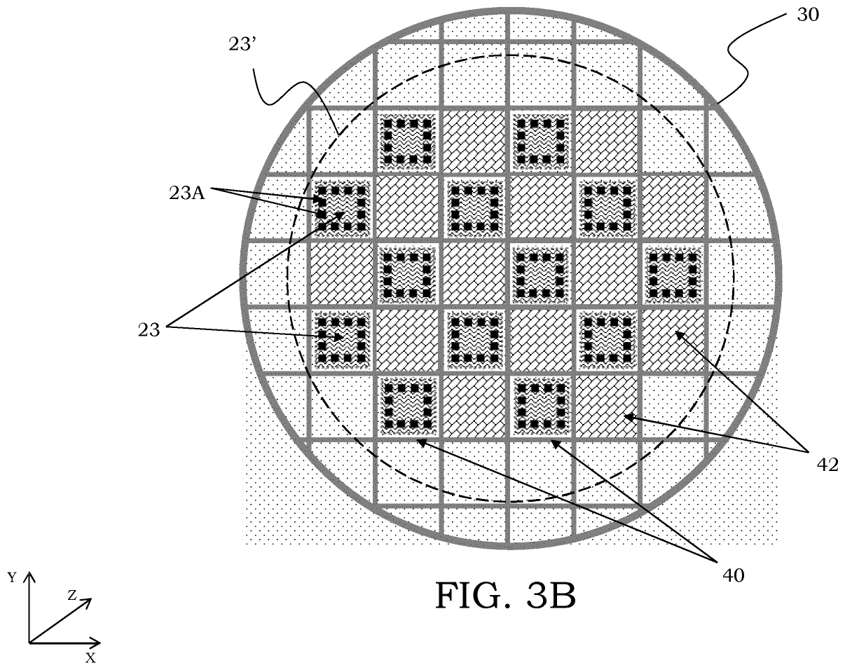

FIG. 3A shows in a simplified top view the positioning of the space transformer 30 and of the modules 40 thereof when the probe card 20 is used to test a semiconductor wafer 23′ comprising a plurality of devices under test 23, in the example shown in the Figure with contact pads 23A arranged in correspondence of two opposite sides of each device under test 23. In the Figure, the probe card 20 is shown with neither the main board 27 nor the stiffener 28.

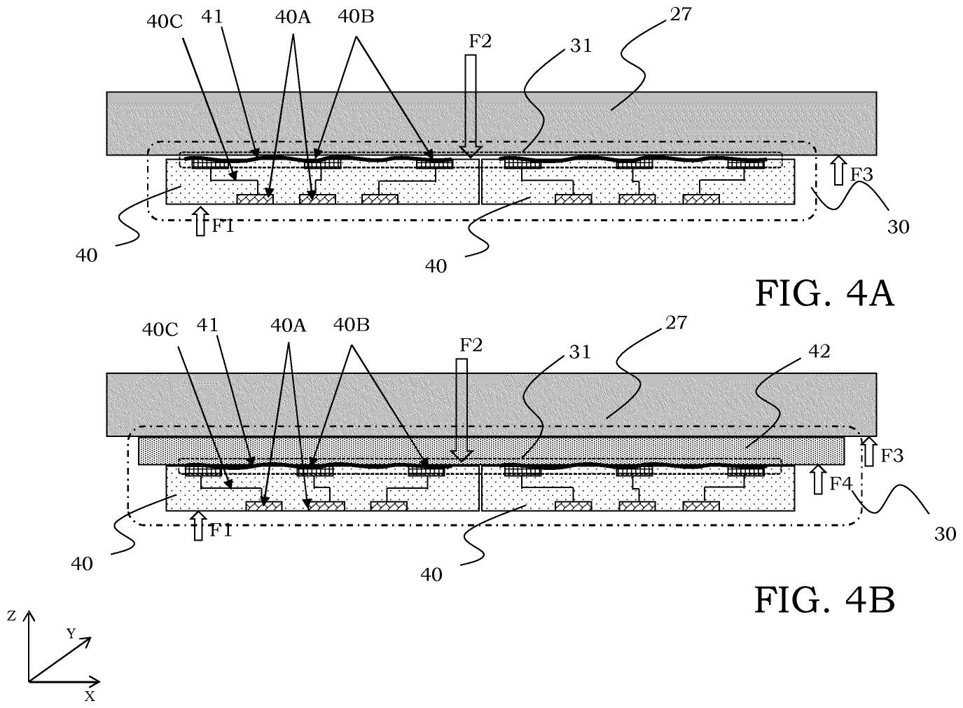

Sectional views of such a space transformer 30 are shown for example in FIGS. 4A and 4B, according to the embodiments of FIGS. 2A and 2B, respectively. In particular, the space transformer 30 of FIG. 4A comprises a plurality of modules 40 integrally connected directly to the main board 27, in particular in correspondence of the face F3 thereof, by means of a plurality of connecting areas 41 that form the connecting structure 31.

As above described, the space transformer 30 comprises a plurality of modules 40 that are adjacent to each other and provided with a first plurality of probe side pads 40A made in correspondence of a first face F1 thereof facing (in operating conditions) towards the probe head 21 and a second plurality of tester side pads 40B made in correspondence of a second face F2 facing (always in operating conditions) towards the main board 27, connected to each other by means of suitable electrical connections 40C. The space transformer 30 also comprises a plurality of connecting areas 41 made in correspondence of the second face F2 of the modules 40 and adapted to form the connecting structure 31 of the space transformer 30.

More particularly, in the embodiment of FIG. 4A, each module 40 comprises a connecting area 41 that integrally connects it to the main board 27 in correspondence of the face F3 thereof facing (in operating conditions) towards the probe head 21 while in the embodiment of FIG. 4B, each module 40 comprises a connecting area 41 that integrally connects it to the support 32 in correspondence of the face F4 thereof facing (in operating conditions) towards the probe head 21, the support 32 being in turn integrally connected to the main board 27 in correspondence of the face F3 thereof.

It is also possible to use the space transformer 30 to make a probe card 20 that can test devices under test 23 having contact pads 23A arranged along all four sides thereof (in a so-called full array configuration); in this case, the space transformer 30 comprises a plurality of separator elements 42, having dimensions, particularly thicknesses, corresponding to the dimensions, particularly thicknesses, of the modules 40 and being coplanar thereto and interspersed in a checkerboard configuration, as schematically illustrated in FIG. 3B. In fact, in this case, it is possible to arrange the contact probes 22 of the probe head 21 associated with the space transformer 30 in a suitably interspersed and spaced apart manner to perform the test of the contact pads 23A of the device under test 23 in a full array configuration and to ensure at the same time that the contact probes 22 do not mechanically or electrically interfere with each other, thereby making a correct routing of the signals provided to said contact probes 22. In a preferred embodiment, the separator elements 42 are also integrally connected to the main board 27 or to the support 32 by means of respective connecting areas 41 arranged on a face F2 thereof facing (in operating conditions) towards the main board 27.

Moreover, one or more of the separator elements 42 can comprise additional components, of the active or passive type, such as capacitors, which can add additional performances to the space transformer 30, such as signal filtering.

As above described, the space transformer 30 comprises a plurality of modules 40 provided with a first plurality of probe side pads 40A made in correspondence of a first face F1 thereof facing (in operating conditions) towards the probe head 21 and a second plurality of tester side pads 40B made in correspondence of a second face F2 facing (always in operating conditions) towards the main board 27, connected to each other by means of suitable electrical connections 40C. The space transformer 30 also comprises a plurality of separator elements 42 that are coplanar and interspersed with the modules 40 in a checkerboard structure, each separator element 42 being interposed between and separating two modules 40.

A plurality of connecting areas 41 made in correspondence of the second face F2 of the modules 40 form the connecting structure 31 of the space transformer 30.

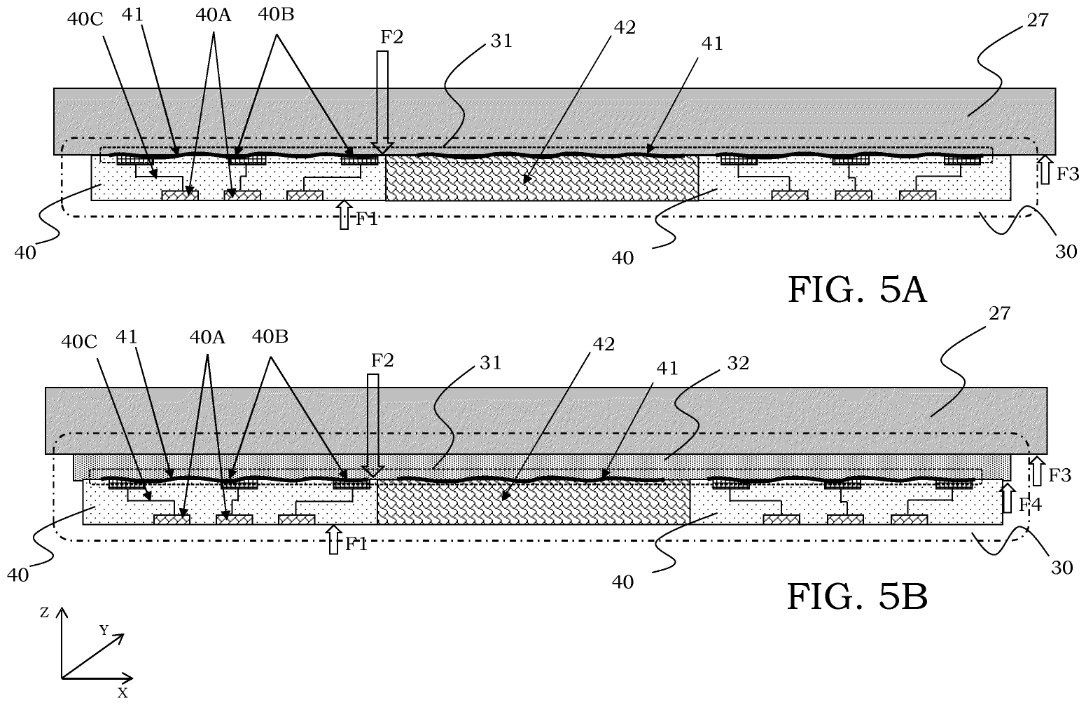

More particularly, in the embodiment of FIG. 5A, each module 40 comprises a connecting area 41 that integrally connects it to the main board 27 in correspondence of the face F3 thereof facing (in operating conditions) towards the probe head 21 while in the embodiment of FIG. 5B, each module 40 comprises a connecting area 41 that integrally connects it to the support 32 in correspondence of the face F4 thereof facing (in operating conditions) towards the probe head 21, the support 32 being in turn integrally connected to the main board 27, in particular in correspondence of the face F3 thereof.

Preferably, each separator element 42 also comprises a connecting area 41 in correspondence of a second face F2 thereof facing (in operating conditions) towards the main board 27.

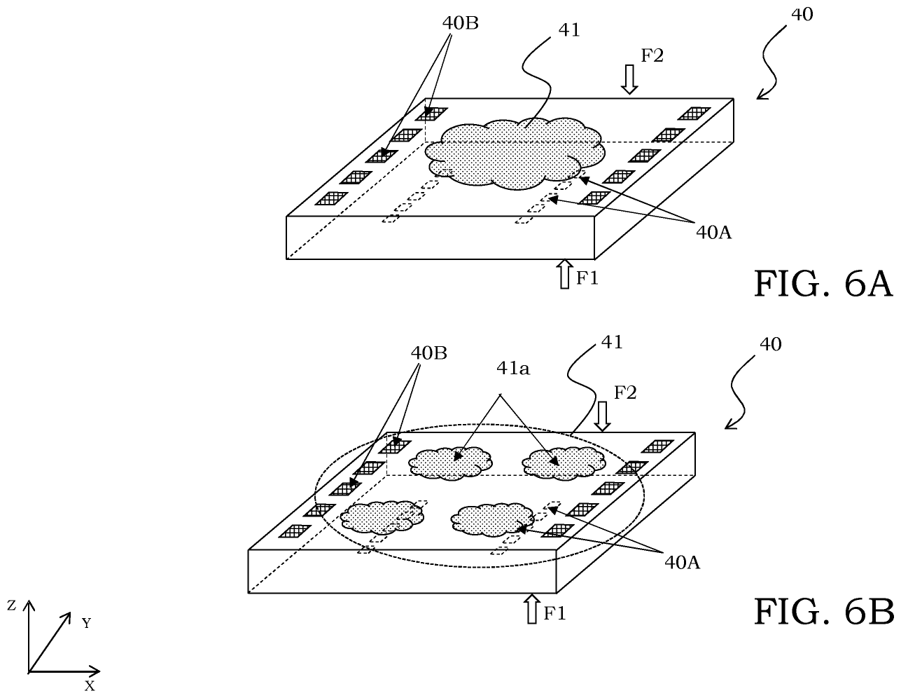

It is possible to make the connecting area 41 with a single area, as schematically illustrated in FIG. 6A, where for the sake of simplicity only one module 40 is depicted. Alternatively, the connecting area 41 can comprise a plurality of connecting areas 41a, that are distinct from each other and arranged on the second face F2 of the module 40.

Furthermore, it should be emphasized that it is possible to make the single modules 40 with other shapes than the prismatic shape with a rectangular base shown in FIGS. 6A and 6B, for example with a prismatic shape with a hexagonal base, a plurality of modules with a hexagonal base being allowed to be side by side so as to efficiently cover a desired area for the space transformer 30.

In conclusion, advantageously according to the invention, a probe card is obtained, that is provided with a space transformer made by means of a plurality of modules that are structurally and functionally independent from each other.

Each module is obviously simpler to make than a large-sized space transformer, with a simplified and advantageously testable (and thus possibly discardable) routing performed by the internal electrical connections before assembling it in the final space transformer, with obvious advantages from the cost and production yield point of view. Moreover, the single modules can be made equal to each other, improving the performances of the space transformer as a whole.

Furthermore, advantageously according to the present invention, each module can be integrally connected in a simple manner on the main board due to the connecting structure made by the plurality of connecting areas, preferably welds, that allow the planarity of the so-obtained space transformer to be ensured.

In an advantageous alternative embodiment, the space transformer also comprises a support, that can be made by means of technologies and materials which can improve the surface planarity thereof, so as to ensure an even more accurate positioning in the z direction of the modules that form said space transformer.

The probe card according to the present invention is thereby suitable for applications in which large-sized wafers and devices with a high number of pads need to be tested.

Furthermore, according to another advantageous alternative embodiment, the modules are interspersed with separator elements so as to allow a correct routing for contact probes adapted to abut onto contact pads arranged on all four sides of a device under test, as in case of full array testing.

Obviously, in order to meet contingent and specific requirements, a person skilled in the art will be allowed to bring various modifications and alternatives to the above-described probe card and space transformer, all falling within the scope of protection of the invention as defined by the following claims.

1. A probe card configured to be mounted in a testing apparatus of electronic devices, comprising:
a probe head that houses a plurality of contact probes, each contact probe having a first end portion configured to abut onto contact pads of a device under test,
a main board, and
an intermediate board, connected to said main board and configured to provide a distance spatial transformation between contact pads made on opposite faces thereof, said intermediate board being a space transformer,
wherein characterized in that said space transformer comprises a plurality of modules that are plate-shaped and coplanar, structurally and functionally independent from each other, each module having a first face facing towards said probe head and provided with a first plurality of contact pads whereonto respective second end portions of said contact probes abut and a second face, opposite said first face and facing towards said main board, said second face being provided in turn with a second plurality of contact pads connected to said first plurality of contact pads by means of electrical connections made inside said module, and
wherein said space transformer comprises a connecting structure made in correspondence of said second faces of said modules, said modules having a same thickness.

2. The probe card according to claim 1, wherein said connecting structure of said space transformer comprises a plurality of connecting areas, each of said connecting areas being made in correspondence of a second face of one of said modules.

3. The probe card according to claim 2, wherein each connecting area comprises an item selected from a the group consisting of: a welding, an adhesive film, an adhesive glue, a conductive adhesive film and a conductive adhesive glue.

4. The probe card according to claim 1, wherein said connecting structure integrally connects said modules of said space transformer to said main board in correspondence of a face thereof facing towards said probe head.

5. The probe card according to claim 4, wherein said face of said main board which said modules are integrally connected to has a surface roughness of less than 5 microns.

6. The probe card according to claim 1, wherein said space transformer further comprises a support and wherein the connecting structure integrally connects said modules of said space transformer to said support in correspondence of a face thereof facing towards said probe head, said support being in turn integrally connected to said main board.

7. The probe card according to claim 6, wherein said face of said support which said modules are integrally connected to has a surface roughness of less than 5 microns.

8. The probe card according to claim 1, wherein said space transformer further comprises a plurality of separator elements that are coplanar to said modules, said separator elements being interposed and interspersed with said modules in a checkerboard configuration, each of said separator elements separating a pair of said modules.

9. The probe card according to claim 8, wherein each of said separator elements comprises a connecting area made in correspondence of a face thereof facing towards said main board, said connecting areas of said separator elements being comprised in said connecting structure of said space transformer.

10. The probe card according to claim 9, wherein at least one of said separator elements comprises components selected from the a group consisting of: active components, and passive components.

11. The probe card according to claim 2, wherein each connecting area is selected from the a group consisting of: a single area, and a plurality of connecting areas that are distinct from each other and arranged on said second face of said modules.

12. The probe card according to claim 1, wherein each of said modules has a plate-like shape, selected from the group consisting of a prismatic shape with a rectangular base and a prismatic shape with a hexagonal base.

13. The probe card according to claim 1, wherein each of said modules comprises a multilayer.

14. A space transformer configured to be inserted into a probe card for a testing apparatus of electronic devices, comprising:
a plurality of modules that are plate-shaped and coplanar, structurally and functionally independent from each other, each module having a first face provided with a first plurality of contact pads and a second face, opposite said first face, said second face being provided in turn with a second plurality of contact pads connected to said first plurality of contact pads by means of electrical connections made inside said module, and
a connecting structure made in correspondence of said second faces of said modules, said modules having a same thickness.

15. The space transformer according to claim 14, wherein said connecting structure comprises a plurality of connecting areas, each of said connecting areas being made at a second face of one of said modules.

16. The space transformer according to claim 15, wherein each connecting area comprises an item selected from the group consisting of a welding, an adhesive film, an adhesive glue, a conductive adhesive film, and a conductive adhesive glue.

17. The space transformer according to claim 14, further comprising a support, said connecting structure integrally connecting said modules to said support in correspondence of a face thereof.

18. The space transformer according to claim 17, wherein said face of said support which said modules are integrally connected to has a surface roughness having a value selected from the group consisting of less than 5 microns, and less than 1 micron.

19. The space transformer according to claim 14, it further comprising a plurality of separator elements that are coplanar to said modules, said separator elements being interposed and interspersed with said modules in a checkerboard configuration, each of said separator elements separating a pair of said modules.

20. The space transformer according to claim 19, wherein each of said separator elements comprises a connecting area made in correspondence of a face thereof aligned and corresponding to said second face of said modules, said connecting areas of said separator elements being comprised in said connecting structure of said space transformer.
